(19) United States
(12) Patent Application Publication
(10) Pub. No.: US 2008/0129613 A1
(43) Pub. Date: Jun. 5, 2008

(54) Calibration for re-configurable active antennas

(75) Inventors: Murat Emre Ermutlu, Helsinki (FI); Jorma Tapio Pallonen, Kirkkonummi (FI)

Correspondence Address: HARRINGTON & SMITH, PC, 4 RESEARCH DRIVE, SHELTON, CT, 06484-6212, US

(73) Assignee: Nokia Corporation

(21) Appl. No.: 11/635,091

(22) Filed: Dec. 5, 2006

(51) Int. Cl. G01R 29/10

(52) U.S. Cl. 343/703

(57) ABSTRACT

A method for calibrating an antenna uses a first and a second antenna element arranged in an array, and a calibration probe that is fixedly located substantially at a phase center of the first and second antenna elements. Phase and amplitude of a signal at each of the first and second antenna elements is measured at the calibration probe. A phase error is determined from a difference between the measured phases, and an amplitude error is determined from a difference between the measured amplitudes. For reception, the phase and amplitude error is applied to align the phases and amplitudes of the signals received at the first and second antenna elements. For transmission, the phase and amplitude error is applied to one signal prior to transmitting parallel signals from both antenna elements. Details are shown for finding the phase center as well as applying the phase and amplitude differences.

### TECHNICAL FIELD

The teachings detailed herein relate to arrayed antenna systems, such as phased array antennas at a base station. It is most particularly related to calibrating active antenna elements of such an array for beam-forming incoming and transmitted signals by adjusting relative phase and amplitudes of those signals.

### BACKGROUND

Continued demand for higher wireless data rates drives advances in multiple aspects of wireless communications systems and methods. Relevant to this invention is beamforming at an array of antenna elements. In such an array, individual antenna elements are used to beamform signals to and from the transceivers connected to those antenna elements so as to add antenna diversity to the wireless signals. Antenna diversity enables the receiver to capture, and the transmitter to emphasize, different wireless pathways that a signal follows between sender and recipient. By resolving these multi-paths and adding to them with MIMO techniques, a fading signal can be more reliably decoded so that less bandwidth is required for re-transmissions and error correction/control. Different active sets of antenna elements in the array may be used at different times and for different signals, so in an ideal case the choice of the active antenna element set is dynamic. Currently, arrayed antenna systems are typically disposed at fixed terrestrial locations such as wireless base stations of a cellular/PCS network, land-based military sensing stations, and in orbiting satellites.

An important consideration in arrayed antenna elements is calibration, specifically phase and amplitude. For a spread spectrum signal, the phase of a signal received at different antennas may vary by the time it reaches the receiver for despreading and decoding, due to different electrical path lengths from antenna element to receiver. These phase errors need to be corrected for proper despreading in a correlator. Further, the signal amplitude or level must also be closely matched at the receiver while the signal is still spread so that both versions can be readily recovered. Because there are multiple antenna elements and the active set of antenna elements changes for different signals and conditions, the problem of calibration is highly complex. The state of the art has evolved several ways to deal with this calibration problem, some of which are noted below.

U.S. Pat. No. 5,477,229 to Caille et al employ a 180 degree phase shifter at each of multiple antennas in an array. These phase shifters are switched successively during a calibration routine to yield measurements used in a transfer function matrix; directly for the case of linear superposition of radiated fields, and iteratively with comparisons to theoretical values in the case of non-linear superposition. This calibration is used during manufacture of the antenna array before the individual antenna elements are assembled into an array. Specifically, a near field probe is placed in front of each source in succession, and the measurements taken at the probe are proportional to the signal received at the receiver.

U.S. Pat. No. 5,530,449 to Wachs et al describes tracking performance of antenna elements, each arranged in a chain with a phase and amplitude compensating network, so as to compensate those individual chains for phase and amplitude error. A probe carrier is switched in time between different chains, to determine different phase and amplitude characteristics for each of the chain (or failure of an individual component of the chain). The amplitude and phase compensating network in an individual chain is then weighted to compensate for the measured values from the probe.

U.S. Pat. No. 6,507,315 to Purdy et al describes calibrating by moving an antenna array and a calibration probe relative to one another so as to characterize all elements of the array simultaneously.

U.S. Pat. No. 6,163,296 to Lier et al appears similar to the '449 patent to Wachs, but describes a switch to change the signal applied to the antenna elements between a calibration and a payload signal, and is therefore seen to necessarily interrupt normal operation during calibration.

US Pat. Publication No. 2004/0063469 to Kawahara et al applies RF couplers to the feed line of each antenna of the array and a summing circuit/power combiner. A probe signal element in a coupler is connected by a signal line to each antenna element. The probe can also be arranged in a cavity of a triangular prism formed by arrayed antenna elements. The base station arrangement described in Kuwahara et al can readily benefit from the advantages of the antenna teachings described herein, and the Kuwahara et al document is hereby incorporated by reference.

The prior art has favored the use of directional couplers to find the relative phase and amplitude differences for signals at different antenna elements or active sets of elements (e.g., a sub-array). For example, prior art FIG. 1 is an image of a calibration network that employs a directional coupler. Apart from complexity, the directional coupler approach is seen to be limited in phase accuracy: a typical phase error between antenna port to calibration port is 8 degrees, and in the worst case it can reach 18 degrees.

Such phase-accurate RF coupling and connection networks impose a constraint in manufacturing of arrayed antennas because it necessarily relies on close tolerances for the physical length (of coaxial cable, microstrip lines, etc.) between the antenna port and the calibration port. A costly measurement system during manufacture is also necessary to account for the true propagation speed of the conductive media between those ports, which typically varies over a fairly broad range for any arbitrary manufacturing lot, so accuracy of the phase electrical length cannot rely on physical length of the conduit alone. In PCB materials used in the antenna elements, the relative dielectric constant εᵣ also typically varies between the x and y directions, so that the signal propagation speeds and hence the electrical lengths vary as a function of direction. However, phase accuracy is a key parameter in effectively using an antenna array system.

Further, it would be advantageous for a calibration system for use not only outside the manufacturing environment in an operational antenna array, but also one that does not require interruption of communications for calibration. That is, a calibration system that can adjust for phase and amplitude error in active antenna elements is particularly useful in that the compensation is of an actual signal rather than a surrogate.

### SUMMARY

The foregoing and other problems are overcome, and other advantages are realized, in accordance with the presently described embodiments of these teachings.

In accordance with an exemplary embodiment of the invention, there is provided an antenna that includes a first and a second antenna element arranged in an array, and a calibration probe disposed substantially at a phase center of the first and second antenna elements. Also included in the antenna is circuitry, coupled to the calibration probe, to measure phase and amplitude of a signal at each of the first and second antenna elements. The circuitry is further to determine a phase error from a difference between the measured phases, and an amplitude error from a difference between the measured amplitudes.

In accordance with another exemplary embodiment of the invention, there is provided a program of machine-readable instructions, tangibly embodied on an information bearing medium and executable by a digital data processor, to perform actions directed toward calibrating antenna elements. In this embodiment, the actions include measuring, at a common probe, a phase for a signal received at each of a first and second antenna element of an array of antenna elements, then determining a phase error from a difference between the measured phases. Further, the actions include correlating the signal received at one of the first and second antenna elements using the phase error.

In accordance with another exemplary embodiment of the invention, there is provided a method for calibrating an antenna. In the method, a first and a second antenna element are provided, arranged in an array. Also provided is a calibration probe that is fixedly located substantially at a phase center of the first and second antenna elements. At the calibration probe, phase and amplitude of a signal at each of the first and second antenna elements is measured. A phase error is determined from a difference between the measured phases, and an amplitude error is determined from a difference between the measured amplitudes.

In accordance with another exemplary embodiment of the invention, there is provided a method for disposing a calibration probe in an antenna array. In this method, a first and a second antenna element are asymmetrically disposed in an array. Then is determined within the array a position that is substantially at a phase center of the asymmetric antenna elements. A calibration probe is fixedly mounted at the determined position, and measure-and-compare circuitry is coupled to the calibration probe.

In accordance with another embodiment of the invention there is provided an apparatus. This apparatus includes calibration means, measuring means, processing means, and an array that has first and second antenna means. The calibration means is disposed substantially at a phase center of the first and second antenna means. The measuring means is coupled to the calibration means, and is particularly adapted to measure at least one of phase and amplitude of a signal at each of the first and second antenna means. The processing means is coupled to the measuring means, and is particularly adapted to determine at least one of a phase error from a difference between the measured phases for the case where the phases are measured by the measuring means, and an amplitude error from a difference between the measured amplitudes for the case where the amplitudes are measured by the measuring means. In a particular embodiment, the first and second antenna means are each active antenna elements, and the calibration means is a calibration probe that is fixedly disposed substantially at a phase center of the first and second antenna elements. The calibration means may also operate as an active antenna element. In this particular embodiment, the measuring means and the processing means are embodied in a digital processor, in which different components or combinations of processor components operate to function as the described measuring means and the processing means.

Further details as to various embodiments and implementations are detailed below.

### BRIEF DESCRIPTION OF THE DRAWINGS

The foregoing and other aspects of these teachings are made more evident in the following Detailed Description, when read in conjunction with the attached Drawing Figures.

FIG. 1 is a plan view of a typical prior art directional coupler calibration network for an 8×4 phased array with polarization diversity.

FIG. 2 is a perspective view of two antenna elements with a probe disposed according to an embodiment of the invention where the calibration probe and antenna elements are symmetric.

FIG. 3 is a graph of amplitudes measured at the calibration probe from the antenna elements of FIG. 2, showing an amplitude difference between them.

FIG. 4 is similar to FIG. 3, but showing measured phase from the antenna elements.

FIG. 5 is similar to FIG. 2 but wherein the probe and antenna elements are not in geometrical symmetry but are in phase symmetry.

FIGS. 6-7 are similar to respective FIGS. 3-4 but for the probe/antenna element configuration of FIG. 5.

FIG. 8 is a perspective view of a probe disposed at an approximate phase center of an 8×2 array of antenna elements according to another embodiment of the invention, each of the antenna elements having two ports or feeds.

FIG. 9 is a graph showing antenna matching for the frequency band 1.8 to 2.0 GHz for the probe/dipole antenna and port A-2 from the configuration of FIG. 8.

FIGS. 10-14 show amplitude and phase differences between different port pairs of FIG. 8 measured at the probe of FIG. 8.

FIG. 15 is a schematic diagram of a base station and related nodes with which it communicates, suitable for employing the present invention.

FIG. 16 is a block diagram of a plurality of transceiver radios in relation to antenna elements and other common functional processing blocks.

FIG. 17 is a schematic block diagram of the transceivers and common processing blocks of FIG. 16 but showing further detail.

FIG. 18 is a process flow diagram of steps in calibrating antenna elements according to an embodiment of the invention.

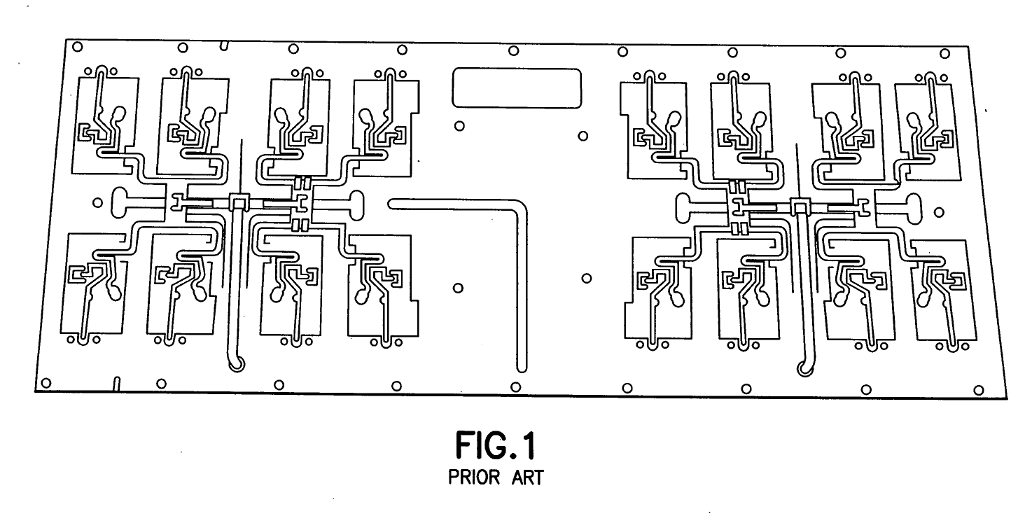

### DETAILED DESCRIPTION OF EMBODIMENTS OF THE INVENTION

The calibration problem has typically been addressed in the prior art during the manufacturing process. These are detailed in the background section. For mass production of arrayed antennas, these manufacturer-based solutions are seen to be time consuming and costly in both materials and labor.

Embodiments of this invention use an antenna/probe instead of a calibration network. The end goal is to obtain relative phase and amplitude information from the antenna elements or sub-arrays of active element sets. Embodiments of this invention do not rely on close manufacturing tolerances for phase electrical length as detailed in the background section, but instead use a calibration probe at the antenna array itself. Costs for the added probe(s) is seen to be in line with costs associated with a directional coupler solution, and embodiments of this invention are characterized in that there is no directional coupler in the calibration circuitry. In embodiments described, the calibration probe(s) can also be used as a transmitting antenna, even while calibrating the array for uplink.

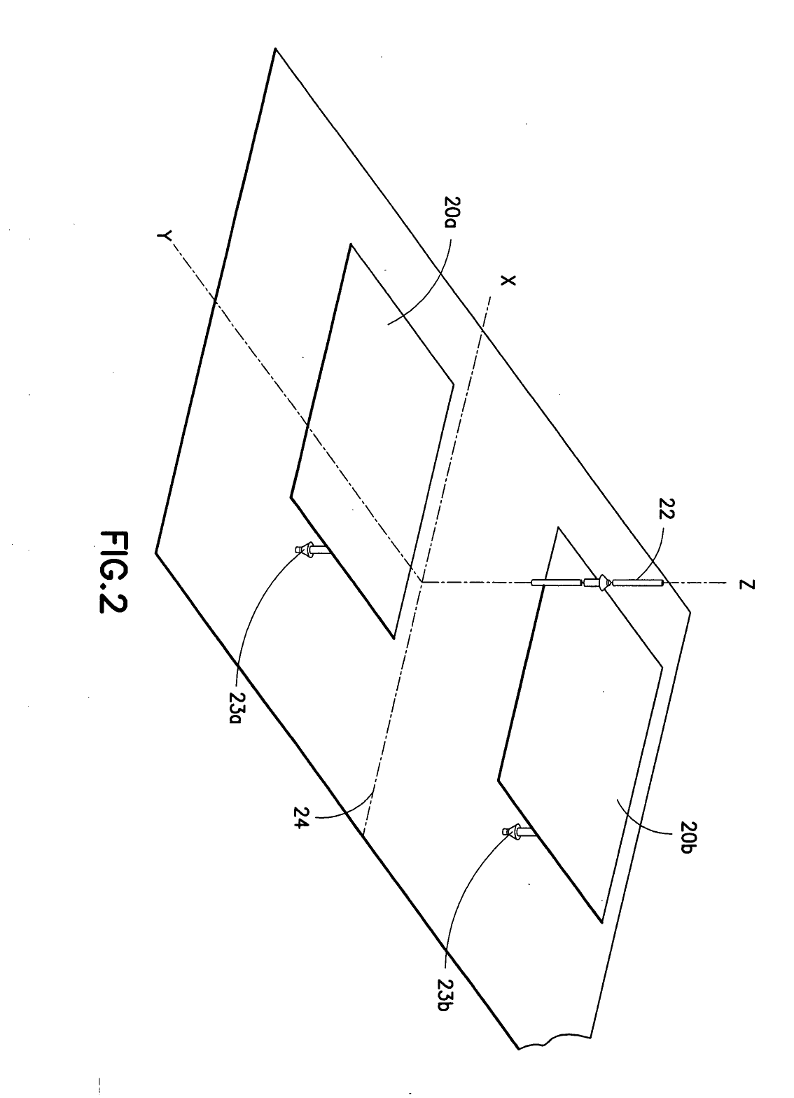

Embodiments of the invention are first described generally with respect to FIGS. 2-8. FIG. 2 illustrates two patch antenna elements 20a, 20b, disposed over a common ground plane 24 with a probe 22 disposed at the phase center of both antenna elements 20a, 20b. Assume for simplicity that each antenna element 20, 20b has only one antenna port 23a, 23b (respectively) or feed point at which signals are input to and output from the antenna element. For the case where the antenna elements 20a, 20b and their ports 23a, 23b are (geometrically) symmetrical (e.g., about the x-z plane as illustrated), their phase center where the probe 22 is to be positioned is simple to find, and known in the art. It will be at the geometric center of the x-y plane in which the antenna elements 20a, 20b lie, and may be disposed above or below that plane along the illustrated z axis. The relative phase and amplitude information is measured at the calibration probe 22, and recorded.

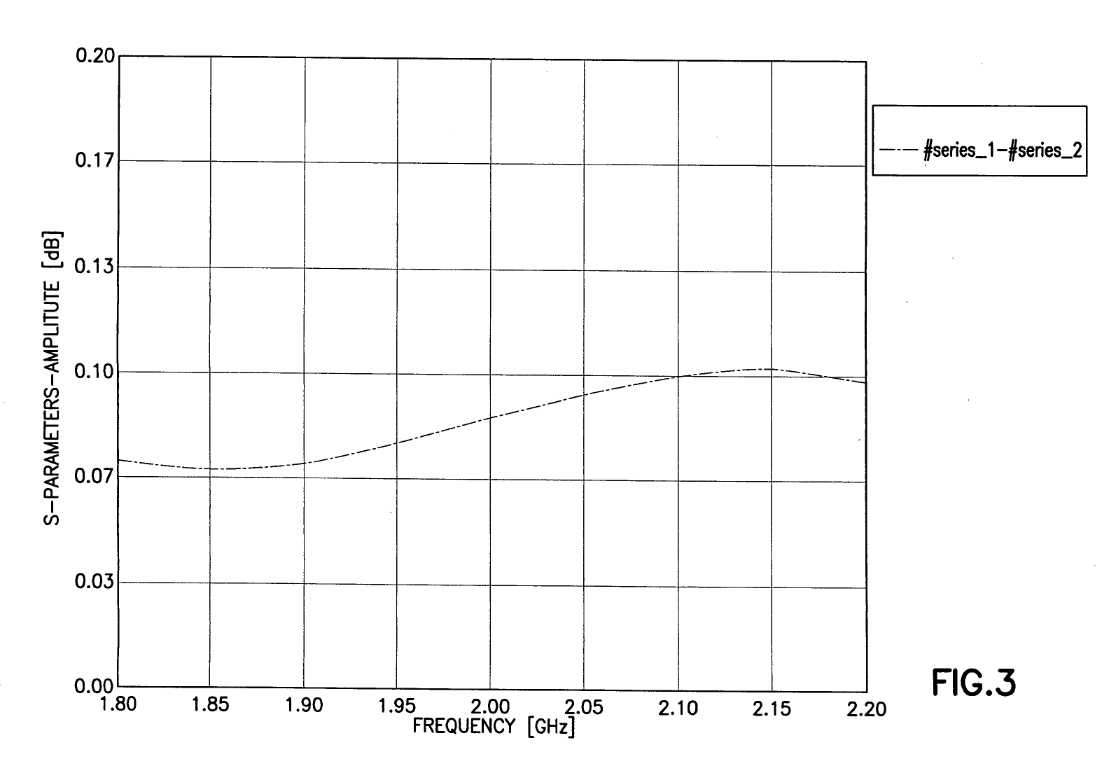

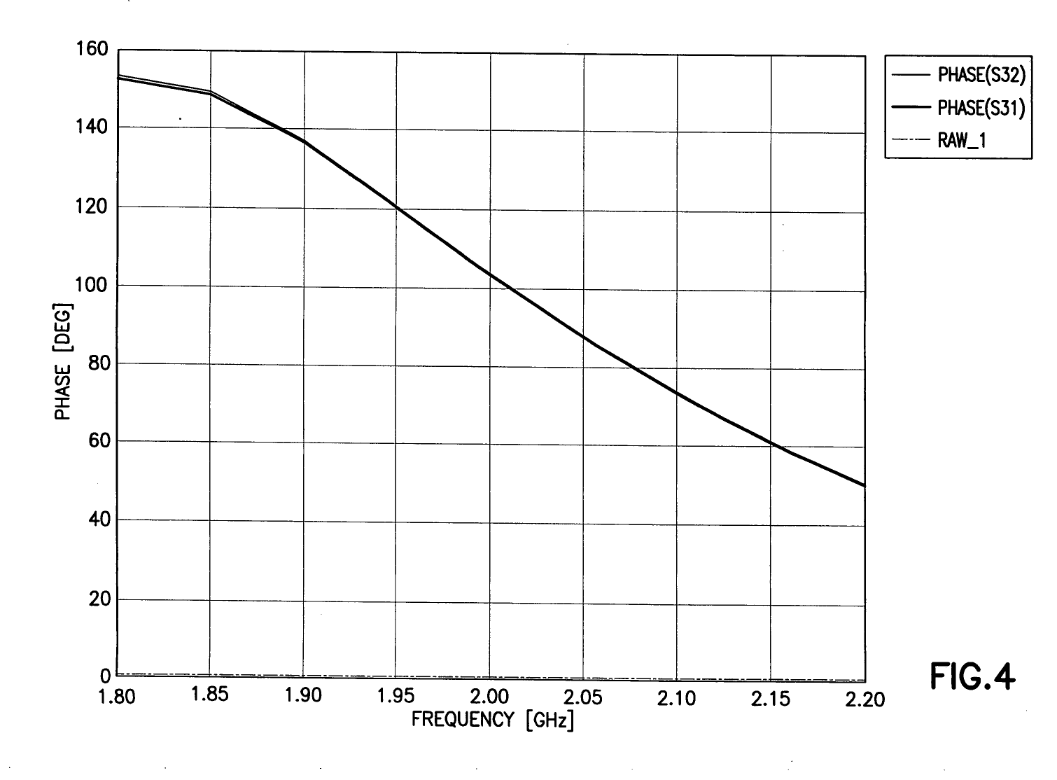

With the properly positioned probe 22, the antenna element S parameters are checked (S13 and S23) and the relative errors in phase and amplitude are determined. FIG. 3 is a graph of amplitude differences measured at the probe 22 for the two antenna elements 20a, 20b of FIG. 2, the symmetrical case. FIG. 4 is a graph of the phase differences for that same arrangement. The amplitude difference is less than 0.105 dB and the phase error in FIG. 4 is less than one degree for the symmetrical arrangement of FIG. 2.

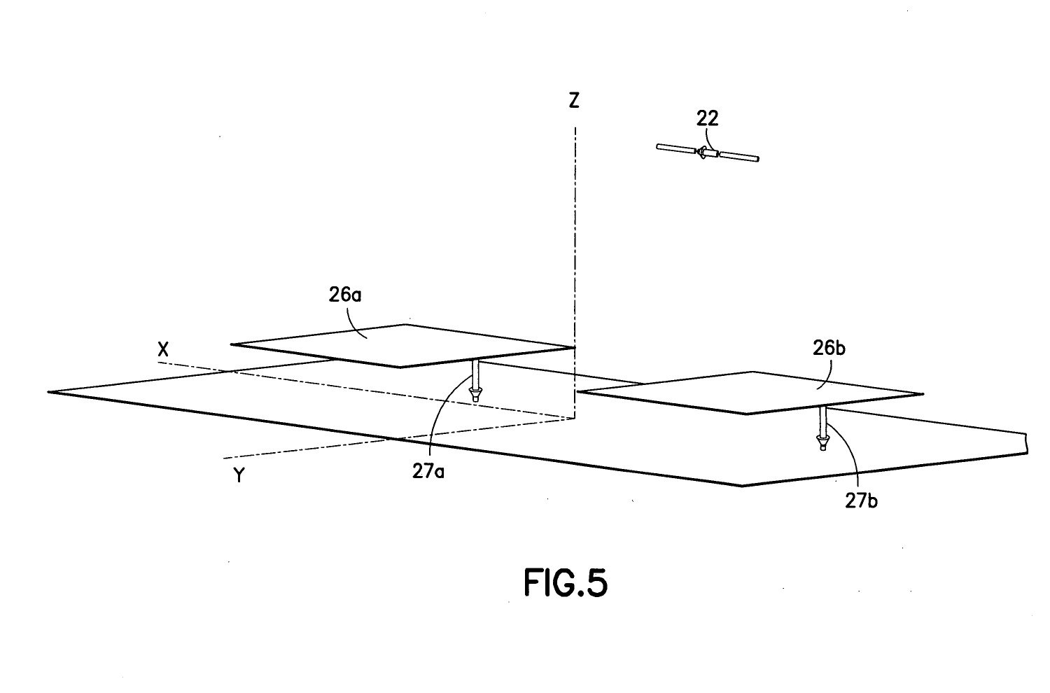

FIG. 5 illustrates two antenna elements 26a, 26b disposed such that their ports 27a, 27b (respectively) are not symmetric with one another. Note that the individual antenna elements 26a, 26b may be identical to one another but only the relative position of their ports 27a, 27b is asymmetric. Symmetric port locations but different orientations of otherwise identical antenna elements 26a, 26b is also an asymmetric disposition. The calibration probe 22 is disposed also at the phase center of those two antenna elements 26a, 26b, but for this non-symmetric case FIG. 5 shows the probe 22 positioned offset from the z axis, which is defined in FIGS. 2 and 5 along the geometric center of those elements 26a, 26b. The exact position of the phase center for the non-symmetric case is not determined as straightforward as for the symmetrical case, but trial and error may be used to find an approximate phase center. As used herein, the term approximate phase center position results in a phase error between the antenna elements 26a, 26b no greater than six degrees, and preferably less than or equal to about five degrees. For the best case, the phase error should be about 0.5 degrees or less. Alternatively, the phase center can be approximated mathematically from the radiation profiles of the individual antenna elements 26a, 26b. Then the probe 22 is used to measure as was done with FIG. 2.

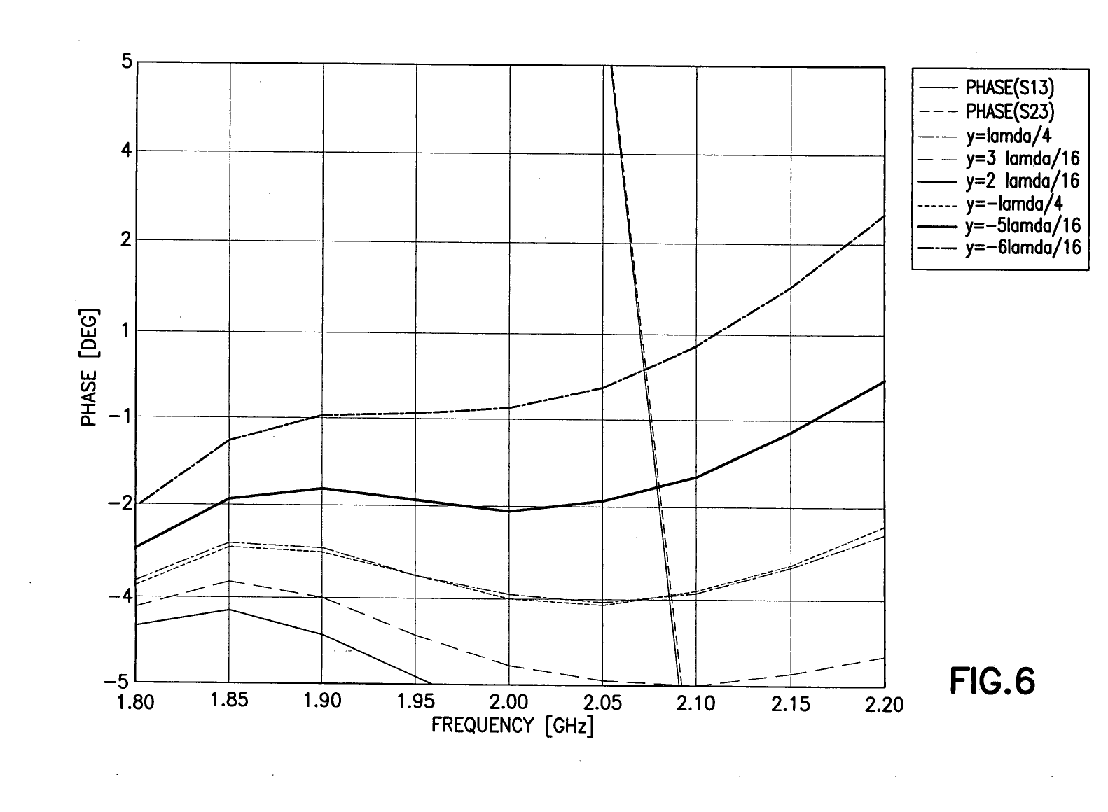

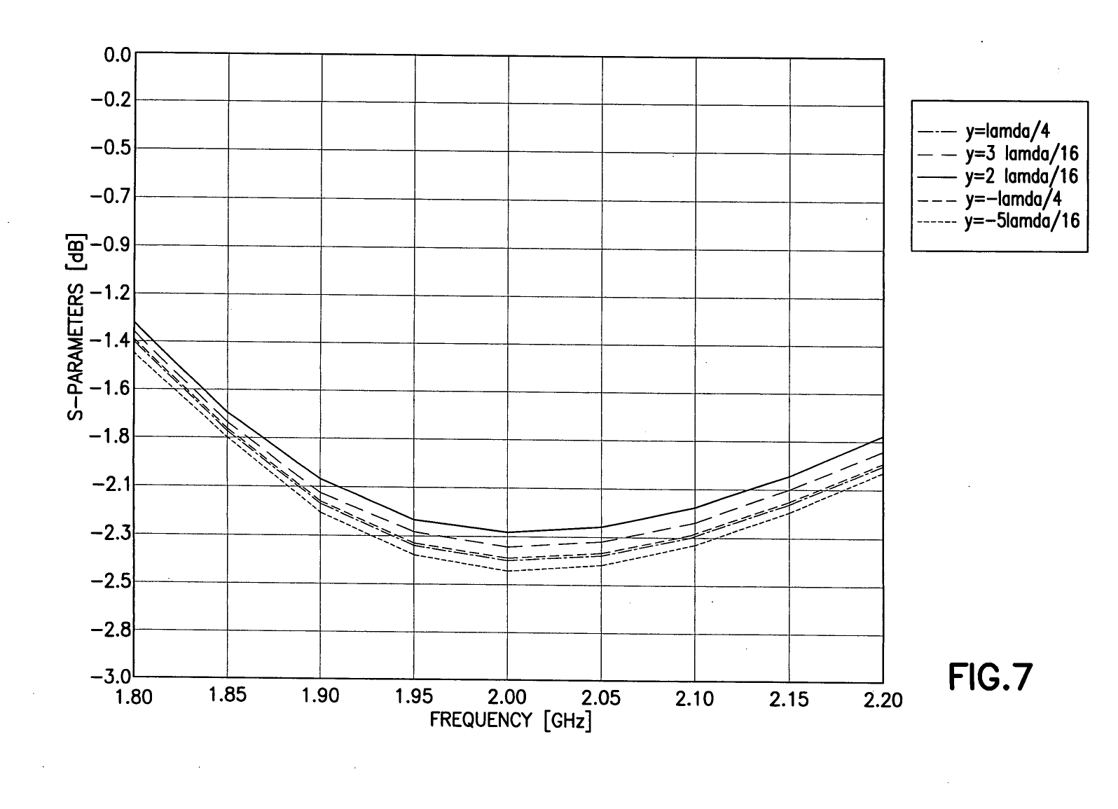

FIGS. 6 and 7 show the respective amplitude and phase errors for the non-symmetrical arrangement of FIG. 5. The amplitude difference measured at the calibration probe 22 shown in FIG. 6 shows far more amplitude error (−1.4 to −2.4 dB) than was seen in FIG. 3, but is acceptable for calibration purposes as will be seen. The same is true for the phase error (+/−2 degrees) measured at the calibration probe 22 and shown in FIG. 7.

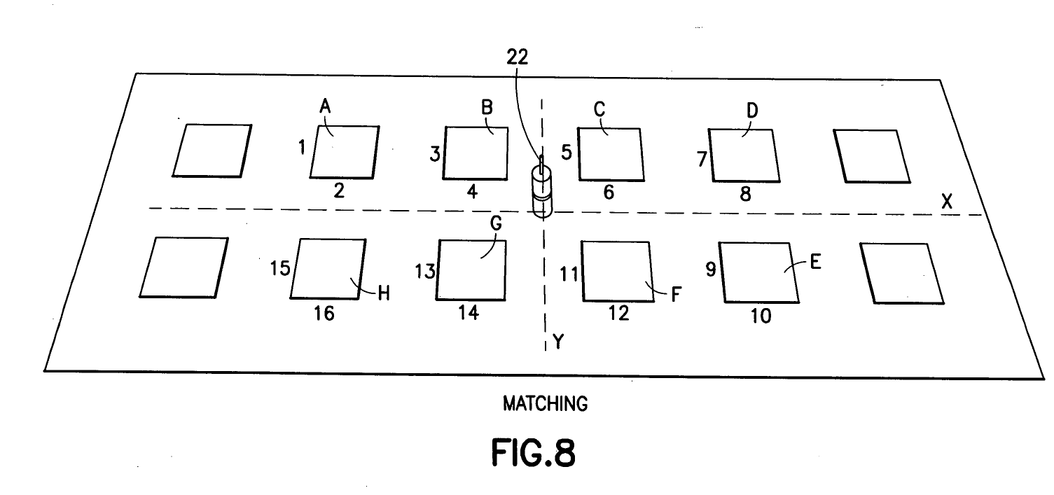

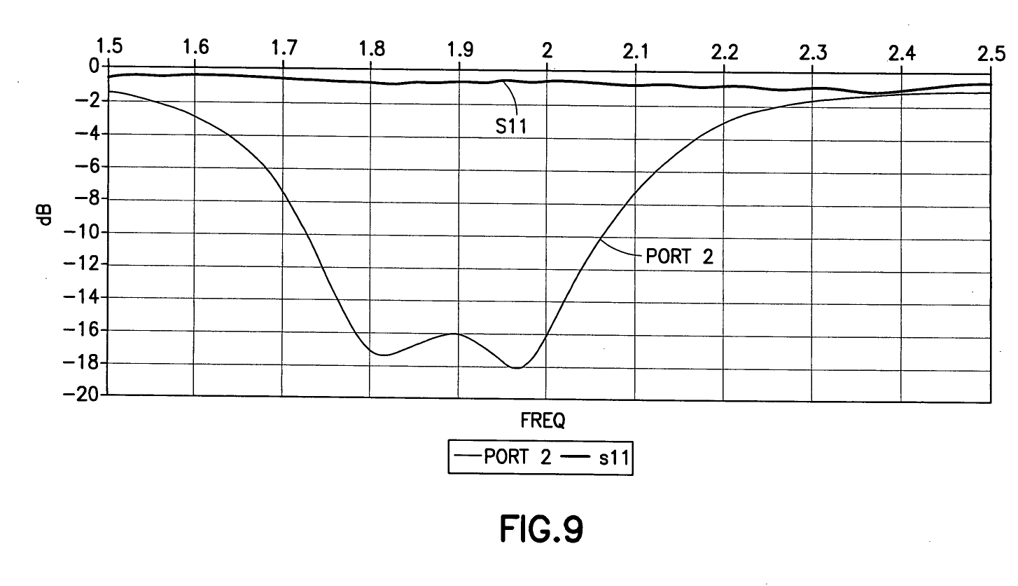

A single calibration probe may be used for calibration of more than two antenna elements or even an entire array of such elements, as is shown in FIG. 8 and the measurement results of FIGS. 9-14. FIG. 8 illustrates an 8×2 array of antenna elements, designated by the capital letters A through H. The two antenna elements at each outboard edge of the illustrated array are not used. For further variation, each antenna element A-H includes two ports, numbered 1 through 16. For convention, these ports will be referred to below only with the letter designation of the associated antenna element; e.g., A-2 for port number 2 that is a part of antenna element A, C-6 for port number 6 of antenna element C, etc. A single calibration probe 22, in this instance a sleeved dipole antenna, is disposed along the geometric center of the antenna elements A-H, shown as the origin of the x-y plane in FIG. 8. Further, the calibration probe 22 is spaced from that x-y plane on which the antenna elements lie as much as possible, 4.9 cm in the results of FIGS. 9-14. Assume for FIG. 8 that each antenna element is physically identical, so the distinction between symmetric pairs of ports and non-symmetric pairs of ports lies only in the relative port location.

FIG. 9 is a graph of frequency versus dB showing measurements at the probe for port A-2, and the S11 parameter. Recall that the calibration probe 22 in this set of measured results is a sleeved dipole. Because that dipole probe 22 is matched for 5.8 GHz, FIG. 9 shows very poor matching with antenna element A for the illustrated frequency range. The range 1.8 to 2.0 GHz is of most interest for these results as that is where the antenna is matched.

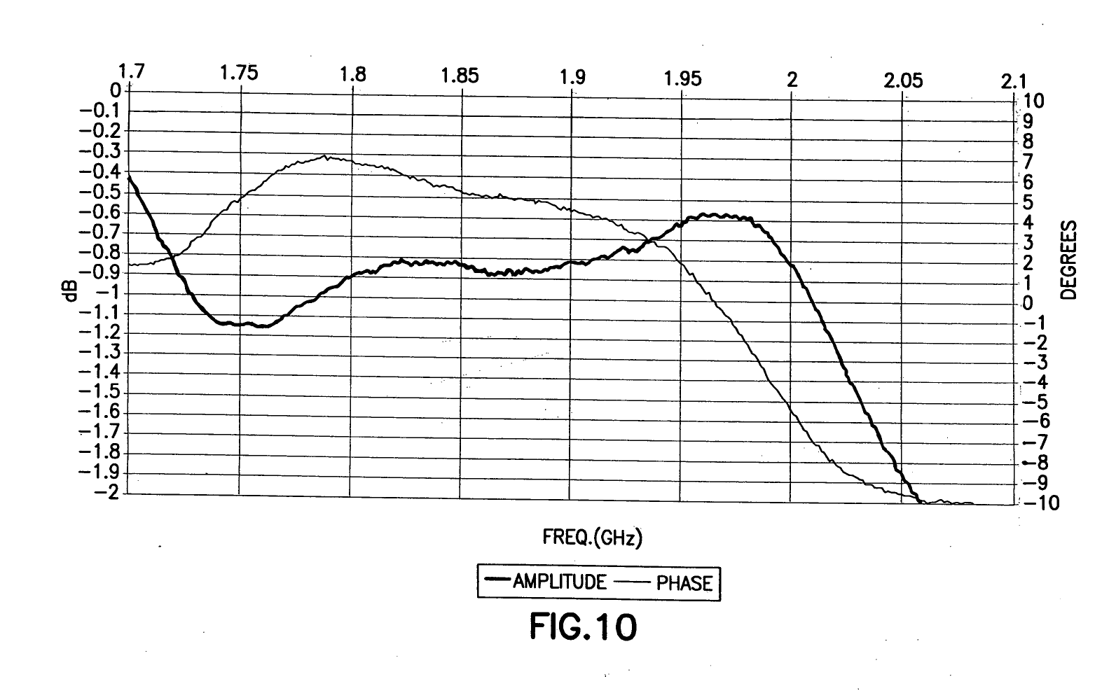

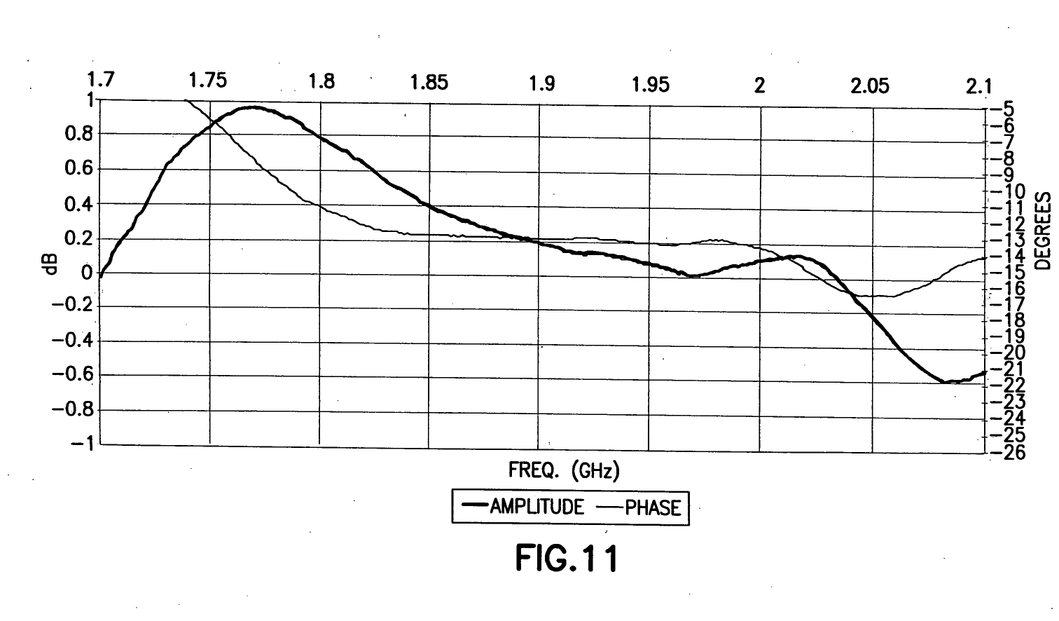

FIGS. 10-14 are measurement results showing feasibility for the probe 22 disposed as in FIG. 8 using different symmetric and asymmetric port pairs in the array. For each, the S-parameters were measured from the probe 22 to each of two different antenna ports, and the difference between those port-measurements is plotted. FIG. 10 shows a graph of frequency versus amplitude (left scale) and versus phase (right scale) for the measured difference between ports A-2 and D-8, which FIG. 8 shows are symmetric. FIG. 10 shows reasonable phase error (6.5 to −6 degrees, or about +/−6 degrees) and amplitude error (−0.3 to −1.5, or about +/−0.6 dB) in the subject frequency range. FIGS. 11-14 use the same charting convention of FIG. 10 for different port pairs.

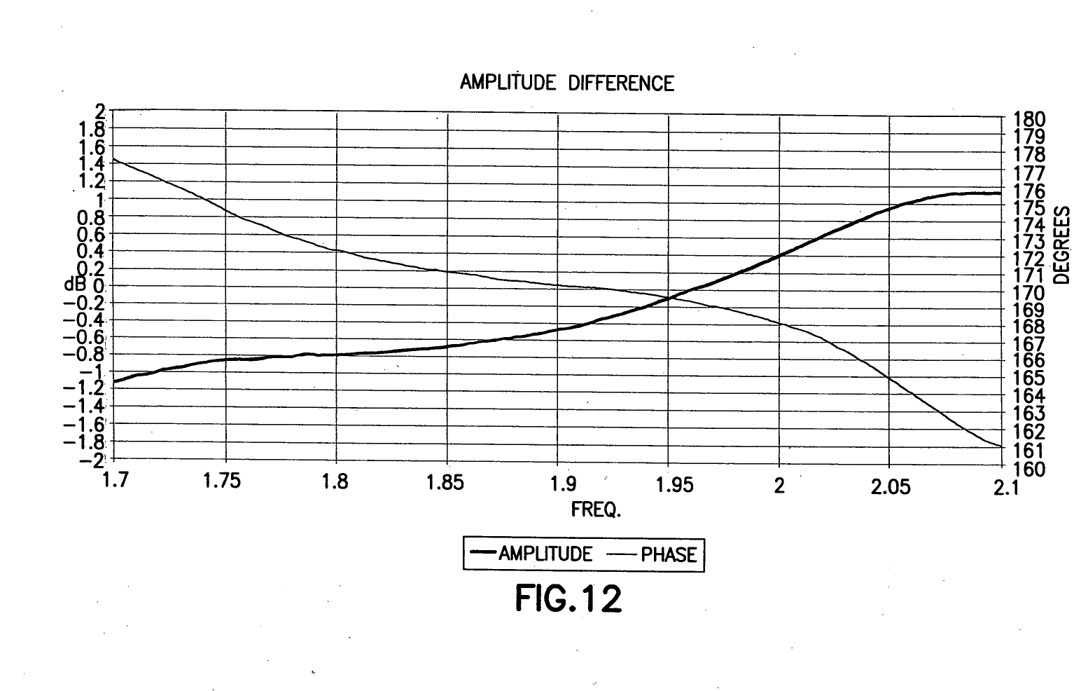

FIG. 11 shows amplitude and phase error for ports B-4 and C-6, also symmetric about the probe 22. Within the range 1.8-2.0 GHz, the amplitude error between them is within +/−0.4 dB and the phase error is within +/−1 degree. FIG. 12 shows results for ports B-3 and C-5, which are asymmetric about the probe 22. The amplitude difference between these ports is the worst of the measurements shown, +/−0.5 dB, while the remains the phase remains within +/−2 degrees in the frequency range of interest.

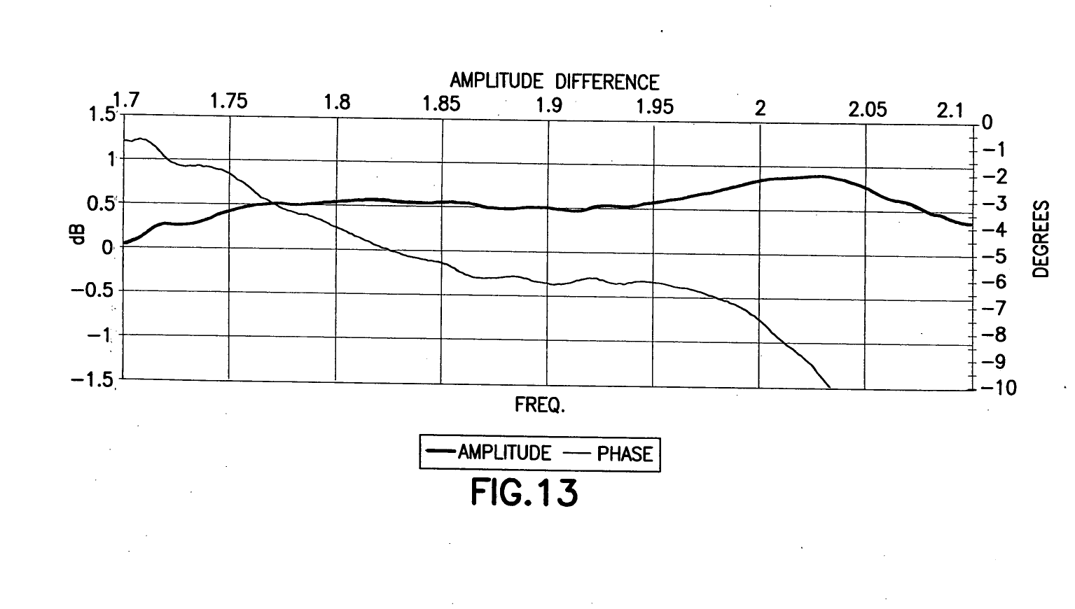

The differences between symmetric ports F-11 and C-5 are shown in FIG. 13. The amplitude is within +/−0.2 dB and the phase remains within +/−1.6 degrees over the frequency range 1.8-2.0 GHz.

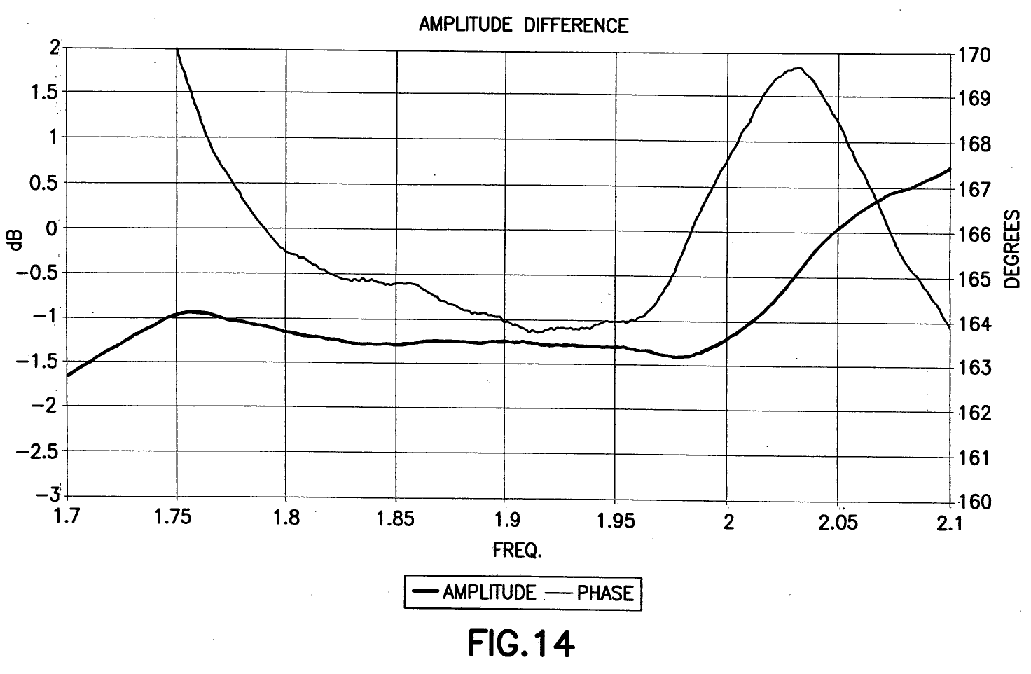

Similar data is shown at FIG. 14 for the differences between asymmetric ports F-12 and C-6. Amplitude difference remains steady and within +/−0.2 dB, and phase difference varies over the band of interest only +/−1 degree. The above data from FIGS. 10-14 show that the probe 22 is verified and working, because the illustrated data can be used to extrapolate among the remaining port pairs, each of which has symmetry or asymmetry similar to one of the measured port pairs. If perfect calibration is needed, an entire array of S parameters may be measured for each port pair in the array.

The focus of the calibration is to accurately change the beam shape (beam-forming) of the phased array antenna system. Properly calibrated, the selection of which antenna elements of the array are to be active for any given signal, and what power and phase are to be applied to the signals to/from each individual element, becomes more accurate and the advantages of MIMO and multipath can be better exploited. Selecting which antenna elements are to be active for a given set of signal conditions is sometimes termed a smart antenna. Before discussing differences in how the calibration results are applied to the uplink versus downlink signals, now are detailed an exemplary environment in which the arrayed antenna may be deployed, and exemplary related hardware/software that may properly apply the calibration results.

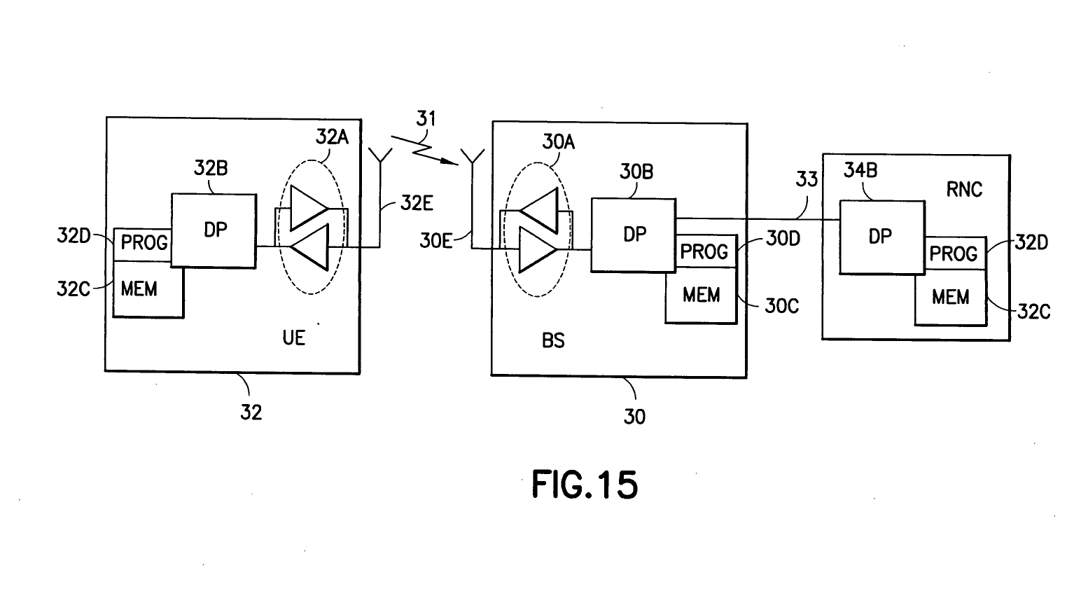

FIG. 15 is a schematic block diagram of a base station BS 30 in which the present invention may be embodied. The present invention may be disposed in any host computing device having a wireless link 31 to another node, whether or not that wireless link is cellular/PCS, IP protocol, or the like. Shown is a user equipment/mobile station MS 32 and a radio network controller 34, with the wireless link 31 between the BS 30 and the MS 32. The link 33 between the BS 32 and higher nodes 34 in the network, such as the RNC 34, is typically a wireline link though in some instances it also may be wireless.

The BS 30 includes a transceiver 30A, a processor 30B, and a computer readable memory 30C for storing software programs 30D of computer instructions executable by the processor 30B for performing actions related to this invention. The BS 30 further has an antenna 30E according to an embodiment of this invention, and the antenna 32E may be an array of selectable active antenna elements. The MS 32 and the RNC 34 have some similar components, indicated in the MS 32 as a transceiver 32A, processor 32B, memory 32C and programs 32D; and in the RNC 34 as a processor 34B, memory 34C and programs 34D. Though not shown, if the link 33 between the BS 32 and the RNC 34 is wireless, the RNC 34 will also include a transceiver and an antenna. Future advances in processing power and antenna physical dimension reductions may enable embodiments of this invention to be incorporated in the antenna 32E of the MS 32.

The component blocks illustrated in FIG. 15 are functional and the functions described below may or may not be performed by a single physical entity as described with reference to FIG. 15. Note that while the following description puts the inventive antenna in the BS 30, that is an exemplary use and non-limiting. Another exemplary use is within an orbiting (communication) satellite or non-orbiting space probe. Within the processor 30B are functions such as digital sampling, decimation, interpolation, encoding and decoding, modulating and demodulating, encrypting and decrypting, spreading and despreading, and additional signal processing functions known in the art for wireless communications.

Known types of antenna elements include monopole, di-pole, planar inverted folded antenna PIFA, and others. A planar element is seen as advantageous for embodiments of this invention. The various antenna elements may be mounted relative to one another by any of various means. A common ground plane as seen in FIGS. 2 and 5 is not essential, and may be disadvantageous for some types of antenna elements where it would facilitate coupling among adjacent active antenna elements.

The BS 30 preferably includes multiple transmitters and multiple receivers, each selectively coupled to more than one, and preferably all, antenna elements of the array. The BS 30 may be configured such that two or more transmitters can transmit a combined signal from different antenna elements or sets of active antenna elements. In such a configuration, one transmitter is termed the slave and the other is termed the master. Such a master/slave transceiver arrangementis seen as a particularly advantageous BS 34 configuration in which to dispose embodiments the present smart antenna calibration, and that reference is hereby incorporated by reference. Embodiments of this invention are seen to replace hardwire path-delay connections between radios so as to compensate for differential path lengths and the resulting phase and amplitude errors when selecting two antenna elements or two transceivers.

Downlink calibration, those for transmissions from the BS 30, can be done in such a manner that different transmitters are compared in pairs so that when two of them are transmitting at the same time, the probe 22 (or at least one probe 22 if more than one is used in an antenna array) is connected to a chain of transceivers for in-phase combining.

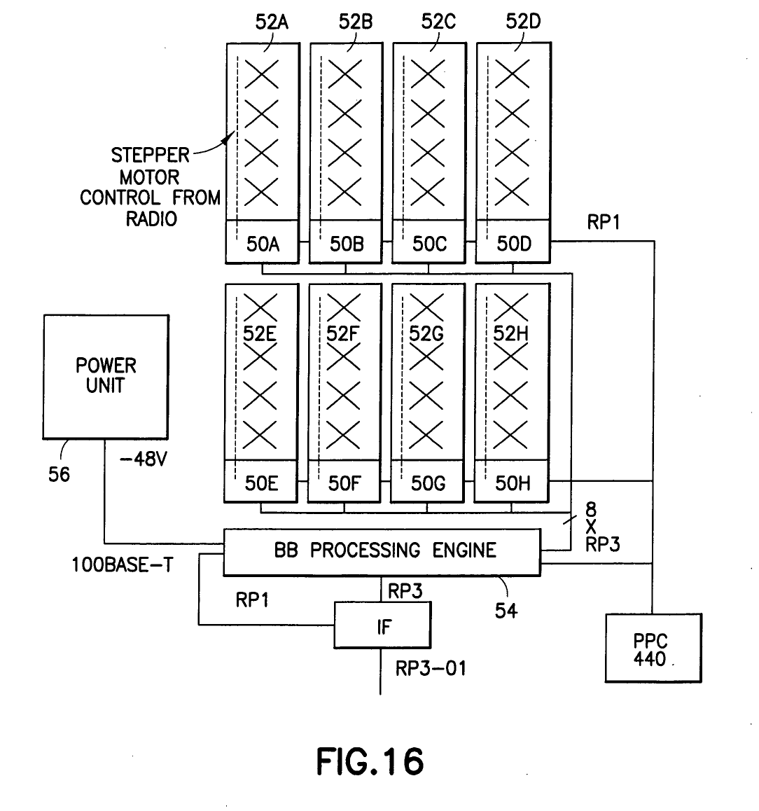

FIG. 16 shows a view of radio transceivers with the antenna array in a BS 30. In this arrangement, there is one transceiver 50A to 50H for each antenna element 52A to 52H, though the connectivity among them may enable any radio to use any antenna element or combination of elements 52A-52H in its transmission or reception active set. A common baseband processing engine 54 handles signals to and from each radio 50A-50H. The radios 50A-50H might be connected differently than is shown in FIG. 16, with redundant connections and variations in electrical path length of those connections being advantageous for robustness of the overall system and accuracy in the path length measurements. Where the phase and amplitude difference is measured at the active antenna elements themselves, as detailed above, there is no need for further measuring different connection path lengths between the radios because that data will already be reflected in the measurements taken by the probe 22 when taken dynamically while the BS 30 is operating. Additionally, since the probe 22 may be an antenna itself as in FIG. 8, there is no need to suspend transmissions or receptions while a calibration measurement is being taken and recorded.

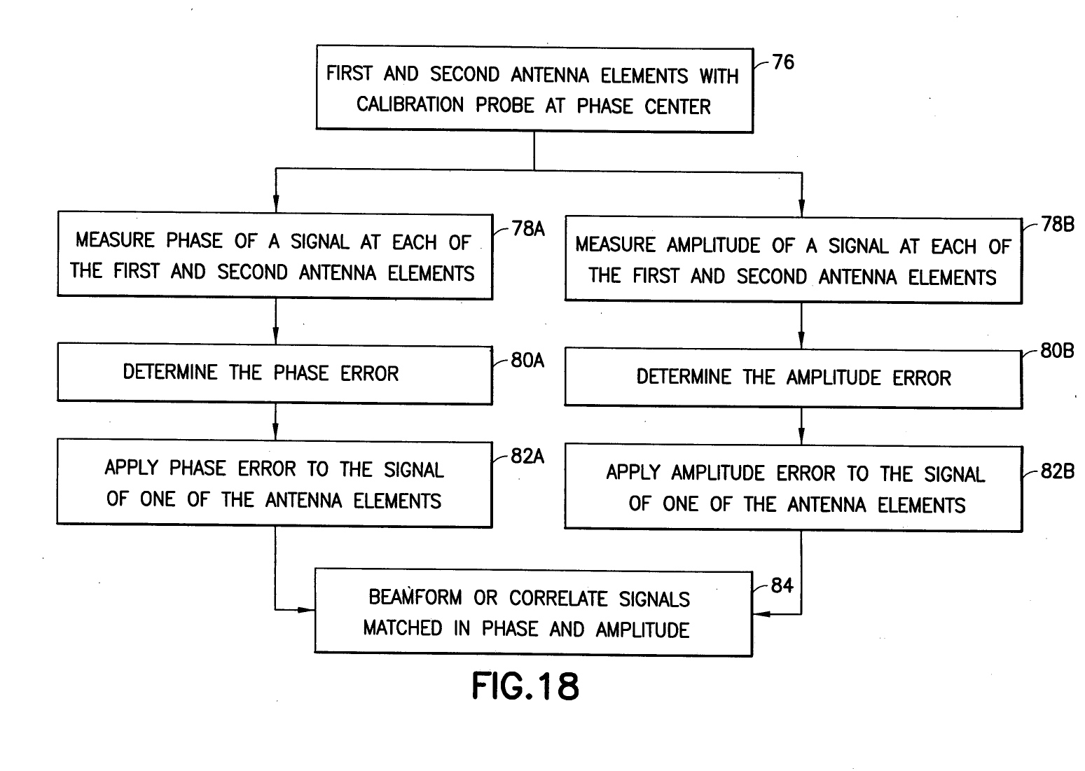

The receivers 50A-50H of FIG. 16 are each coupled to a common baseband BB processing block 54, commonly termed a correlator or including a correlator. Typically, this block 54 will be an application specific integrated circuit ASIC. In this arrangement, extensive beamforming is not done at the antenna elements themselves, but rather in the baseband processing of a received signal at the BS 30. The signal to the respective antenna elements is already beamformed. The correlator can also be located in the multiplexer unit (see FIG. 18) that combines the separate data streams prior to the common pathway for transmit signals. The phase and amplitude differences found by the calibration probe 22 according to this invention can be applied at the correlator.

The BB processing block 54 contains the correlator for despreading and complex multipliers for the phase difference measurement and adjustment. An alternative embodiment is to use one of the receivers for phase difference measurement, but then the RF loop of the transmitter would be used to down convert the downlink signals to the uplink frequency band so the receiver can properly process it. The conversion should be done in the receiving end of the calibration system, rather than a separate upconversion for each transmission pathway. Otherwise, there is an opportunity to introduce up to a 360 degree error source (e.g., two separate transmission loops) in the calibration chain. The receiver RF baseband also includes some means, preferably the same means of a correlator and complex multiplier, as in the uplink calibration. Alternatively, additional hardware can be added for dedicated uplink calibrator functionality.

Uplink calibration uses a phase correlator, as that hardware is present already for the I and Q streams where they are available simultaneously for the first time in uplink signal processing. In a traditional adaptive antenna or MIMO, this is within the base band processing of the BS 30, so it is a known functionality and well tested over time.

When making a configurable active antenna the first common point is inside the common digital unit that makes the illumination function calculation and settings for both the uplink and downlink signals. The illumination function includes the phase and amplitude adjustments to yield the desired radiation pattern from the combined active antenna elements. The receivers are calibrated so that each two receivers are compared in pairs, and the phase and power settings are adjusted until the illumination function is as desired. Typically the initial illumination function set is flat i.e. all the radios are in phase and there is no power tapering. The desired adjustments can be done as forward adjustment without feedback, or confirmed with some feedback measurement that is re-applied at the phase correlator.

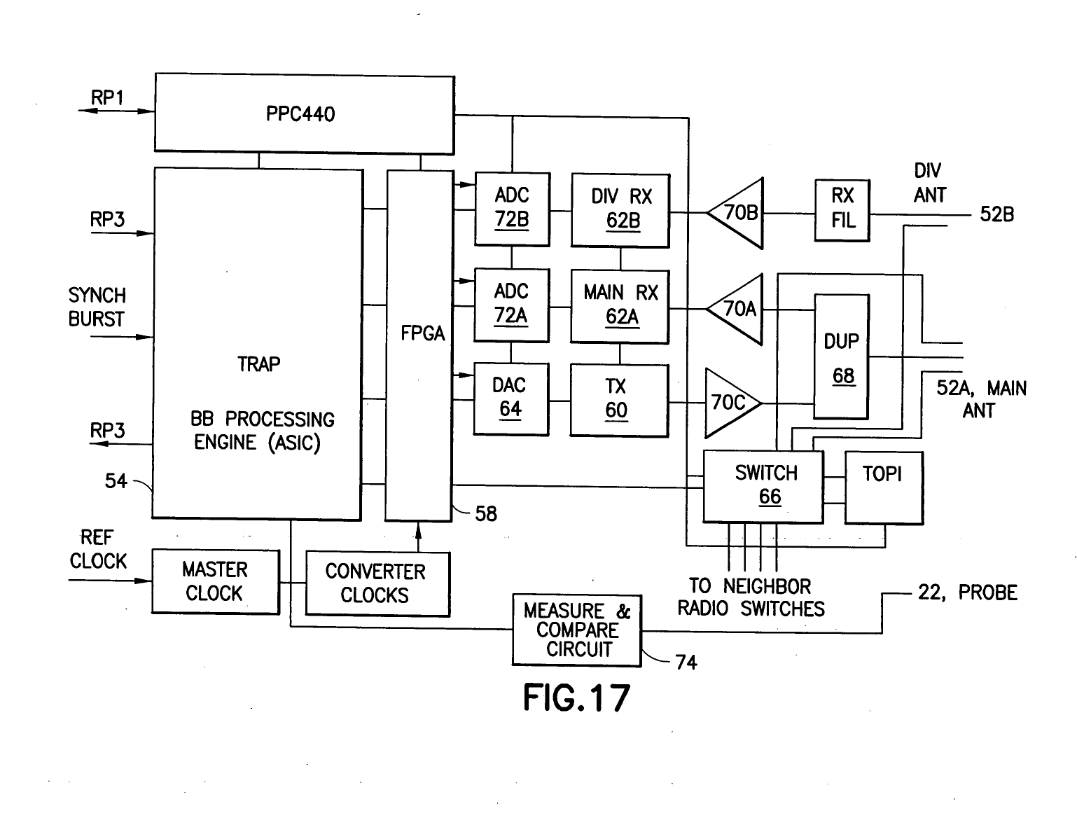

FIG. 17 is a schematic block diagram showing further detail from FIG. 16 for one transmitter 60 and a pair of receivers 62A, 62B coupled to a main antenna element 52A and a diversity antenna element 52B. The baseband processing block 54 is from FIG. 16 and is where the correlator is located and where the phase errors as detailed above are applied. FIG. 17 describes applying the phase and amplitude error for a received signal, though similar processing in reverse is done for transmit diversity and beamforming. A signal is received at each of the main 52A and diversity 52B antennas, each received signal is split, and passed in one instance to a switch 66 that enables further receivers to be switched in and out to process the signal similarly as will be described for FIG. 17. In the other instance of the split signal, a diplex filter 68 directs the signal from the main antenna 52A to an amplifier 70A and the main receiver 62A where it is demodulated and downconverted. An analog to digital converter ADC 72A converts the signal from the main receiver 62A to digital, after which it passes through a field programmable gated array FPGA 58 and into the BB processing block 54. The signal from the diversity antenna 52B follows a similar path through a diversity receiver 62B. Both signals are present together for the first time in the BB processing block 54, so the phase difference measured as detailed above is compensated at the correlator located in that block 54. The amplitude difference may also be compensated at that same BB processing block 54, or at the FPGA 58. The probe 22 detects the phase and amplitude of the signal at the main antenna 52A and at the diversity antenna 52B. Those phases and amplitudes are compared at a measure and compare circuit 74 to determine the difference, or phase and amplitude error. Those error values are then input to the BB processing block 54 where they are applied at one or both correlators (phase error) to align phases of the signals from the respective antennas 52A, 52B that are being despread, and at an amplifier or gain control mechanism for one or both of the signals from those respective antennas 52A, 52B. As noted, those amplifiers are preferably also in the BB processing block 54 but need not be; the amplitude error correction may be applied to the amplifiers 70A, 70B prior to the receivers 62A, 62B, but some signal level error may be later introduced in the pathway between those amplifiers 70A, 70B and the BB processing block 54.

As was noted above, embodiments of this invention may also be advantageously employed in the base station circuitry described in US pat. Pub. No. 2004/0063469 to Kuwahara et al, incorporated by reference, to compensate phase and amplitude errors in a signal sent from or received at multiple antenna elements of an array.

In summary, embodiments of the present invention dispense with the need of directional coupler solutions to build a different calibration network for every antenna element or sub-array of active elements. In some cases only one calibration antenna/probe 22 is sufficient, yielding a savings in material cost. Further, complexity is decreased as compared to directional couplers, so the costs of mass production of embodiments of this invention should be in line with costs for directional coupler solutions. Unique to this invention is the capability to use the calibration antenna/probe 22 as a transmitter antenna for uplink calibration. In the directional coupler solutions, one of the phase array antenna elements or sub-arrays must be for uplink calibration.

FIG. 18 is a flow diagram of process steps for calibrating antenna elements of an array according to an embodiment of the invention. At block 76, an array of first and second antenna elements (more can be included as above) is provided with a calibration probe disposed at the phase center, or substantially (within six degrees) at the phase center of those elements. At block 78A, the phase is measured at the probe for a signal at the first antenna element, and at the second antenna element. At block 80A, the phase difference or phase error is determined from the measured phases, and at block 82A the phase error is applied to the signal to or from one of the antenna elements. Similar processing occurs at blocks 78B, 80B, and 82B for amplitude. Once phase and amplitude error is applied to one of the two parallel signals, they are either beamformed for transmission or correlated in reception. Note that the phase and amplitude errors may be determined from and applied to the same signal that is received; there is no need to interrupt payload operations to calibrate. Specific and exemplary points/functional blocks at which the errors may be applied are detailed above.

The embodiments of this invention may be implemented by computer software executable by a data processor of the host device, such as the processor 30B, or by hardware, or by a combination of software and hardware. Further in this regard it should be noted that the various blocks of the logic flow diagram of FIG. 17 may represent program steps, or interconnected logic circuits, blocks and functions, or a combination of program steps and logic circuits, blocks and functions.

The memory or memories 32C may be of any type suitable to the local technical environment and may be implemented using any suitable data storage technology, such as semiconductor-based memory devices, magnetic memory devices and systems, optical memory devices and systems, fixed memory and removable memory. The data processor(s) 30B may be of any type suitable to the local technical environment, and may include one or more of general purpose computers, special purpose computers, microprocessors, digital signal processors (DSPs) and processors based on a multi-core processor architecture, as non-limiting examples.

In general, the various embodiments may be implemented in hardware or special purpose circuits, software, logic or any combination thereof. For example, some aspects may be implemented in hardware, while other aspects may be implemented in firmware or software which may be executed by a controller, microprocessor or other computing device, although the invention is not limited thereto. While various aspects of the invention may be illustrated and described as block diagrams, flow charts, or using some other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof. Further, those claims employing the term “comprising” are seen to encompass embodiments that include the recited features in combination with other features that are not explicitly recited.

Embodiments of the inventions may be practiced in various components such as integrated circuit modules. The design of integrated circuits is by and large a highly automated process. Complex and powerful software tools are available for converting a logic level design into a semiconductor circuit design ready to be etched and formed on a semiconductor substrate.

Programs, such as those provided by Synopsys, Inc. of Mountain View, Calif. and Cadence Design, of San Jose, Calif. automatically route conductors and locate components on a semiconductor chip using well established rules of design as well as libraries of pre-stored design modules. Once the design for a semiconductor circuit has been completed, the resultant design, in a standardized electronic format (e.g., Opus, GDSII, or the like) may be transmitted to a semiconductor fabrication facility or “fab” for fabrication.

Although described in the context of particular embodiments, it will be apparent to those skilled in the art that a number of modifications and various changes to these teachings may occur. Thus, while the invention has been particularly shown and described with respect to one or more embodiments thereof, it will be understood by those skilled in the art that certain modifications or changes may be made therein without departing from the scope and spirit of the invention as set forth above, or from the scope of the ensuing claims.

What is claimed is:

1. An antenna comprising:
a first and a second antenna element arranged in an array;
a calibration probe disposed substantially at a phase center of the first and second antenna elements;
circuitry coupled to the calibration probe to measure phase and amplitude of a signal at each of the first and second antenna elements and to determine a phase error from a difference between the measured phases and an amplitude error from a difference between the measured amplitudes.

2. The antenna of claim 1, wherein the first and second antenna elements are arranged asymmetrically with respect to the calibration probe.

3. The antenna of claim 1, wherein substantially at a phase center comprises a position such that the phase error is no greater than six degrees.

4. The antenna of claim 1, further comprising a plurality of additional antenna elements arranged in the array, wherein the calibration probe is disposed substantially at the phase center of any pair of antenna elements of the array.

5. The antenna of claim 1, further comprising a plurality of N additional antenna elements arranged in the array and N/2 additional calibration probes disposed such that each of the N/2 calibration probes is disposed substantially at a phase center of a unique pair of the N antenna elements

6. The antenna of claim 1, wherein the first and second antenna elements are patch antenna elements arranged in a planar array.

7. The antenna of claim 1, wherein each of the first and second antenna elements comprise a first and a second port, and the calibration probe is disposed substantially at a phase center of any pair of ports wherein one port of any given pair is of the first antenna element and the other port of the given pair is of the second antenna element.

8. The antenna of claim 1 further comprising a baseband processing block coupled to the circuitry for applying at least the phase error to a signal received at one of the first and second antenna elements, wherein the baseband processing block is further coupled to a first signal line from the first antenna element and a second signal line from the second antenna element.

9. The antenna of claim 8, wherein the baseband processing block comprises a correlator at which the phase error is applied.

10. The antenna of claim 1 disposed within a base transceiver station, the base transceiver station further comprising:
at least two transceivers each selectively coupled to the first and second antenna elements and coupled to the circuitry, and configured to beamform a transmit signal at the first and second antenna elements using the phase error and the amplitude error.

11. The antenna of claim 10, wherein the calibration probe comprises a further antenna element and at least one of the transceivers is coupled so as to transmit from the further antenna element.

12. A program of machine-readable instructions, tangibly embodied on an information bearing medium and executable by a digital data processor, to perform actions directed toward calibrating antenna elements, the actions comprising:
at a common probe, measuring a phase for a signal received at each of a first and second antenna element of an array of antenna elements;
determining a phase error from a difference between the measured phases; and
correlating the signal received at one of the first and second antenna elements using the phase error.

13. The program of claim 12, further comprising:
at the common probe, measuring an amplitude of the received signal at each of the first and second antenna elements;
determining an amplitude error from a difference between the measured amplitudes; and
adjusting gain of the signal received at one of the first and second antenna elements using the amplitude error.

14. The program of claim 12, wherein the probe is disposed substantially at a phase center of the first and second antenna elements.

15. A method for calibrating an antenna comprising:
providing a first and a second antenna element arranged in an array and a calibration probe fixedly located substantially at a phase center of the first and second antenna elements;
measuring at the calibration probe phase and amplitude of a signal at each of the first and second antenna elements; and
determining a phase error from a difference between the measured phases and an amplitude error from a difference between the measured amplitudes.

16. The method of claim 15, wherein the first and second antenna elements are arranged asymmetrically with respect to the calibration probe.

17. The method of claim 15, wherein the signal is wirelessly received at each of the first and second antenna elements, measuring comprises measuring the phase and determining comprises determining the phase error, the method further comprising:
applying the phase error to the signal wirelessly received at the first antenna element so as to align it in phase with the signal wirelessly received at the second antenna element.

18. The method of claim 15, wherein measuring comprises measuring the amplitude and determining comprises determining the amplitude error, the method further comprising:
applying the amplitude error to the signal wirelessly received at one of the first and second antenna elements so as to match in amplitude with the signal wirelessly received at the other of the first and second antenna elements.

19. The method of claim 17, wherein applying the phase error comprises correlating the signal wirelessly received at the first antenna element.

20. A method for disposing a calibration probe in an antenna array, comprising:
asymmetrically disposing a first and a second antenna element in an array;
determining within the array a position that is substantially at a phase center of the asymmetric antenna elements;
fixedly mounting a calibration probe at the determined position; and
coupling measure-and-compare circuitry to the calibration probe.

21. The method of claim 20, wherein each of the first and second antenna elements comprise a first port, and asymmetrically disposing comprises disposing the first and second antenna elements such that their respective first ports are asymmetric.

22. The method of claim 21, wherein each of the first and second antenna elements each comprise multiple ports.

23. The method of claim 21, further comprising coupling the measure-and-compare circuitry to a baseband processing block and coupling in parallel at least two transceivers between the baseband processing block and the first and second antenna elements.

24. The program of claim 12, wherein the information bearing medium, the digital data processor, the common probe, and the first and second antenna elements are disposed in a base transceiver station.

25. The method of claim 15, wherein measuring at the calibration probe comprises measuring both phase and amplitude of the signal at each of the first and second antenna elements; and
determining comprises determining both the phase error from the difference between the measured phases and the amplitude error from the difference between the measured amplitudes.

26. An apparatus comprising:
an array comprising first and second antenna means;
calibration means disposed substantially at a phase center of the first and second antenna means;
measuring means coupled to the calibration means and adapted to measure at least one of phase and amplitude of a signal at each of the first and second antenna means;
processing means coupled to the measuring means and adapted to determine at least one of a phase error from a difference between the measured phases and an amplitude error from a difference between the measured amplitudes.

27. The apparatus of claim 26, wherein:
the first and second antenna means comprise antenna elements;
the calibration means comprises a calibration probe; and
the measuring means and the processing means comprise a digital processor.

28. The apparatus of claim 26 disposed within a base transceiver station, the base transceiver station further comprising:
a first transceiver coupled to the first antenna means;
a second transceiver coupled to the second antenna means;
and wherein the processing means is configured to cause the first and second transceivers to beamform a signal from the first and second transceivers and transmitted from the first and second antenna means using the determined phase error.

29. The apparatus of claim 26, wherein
the measuring means is adapted to measure both the phase and the amplitude of a signal at each of the first and second antenna means; and
the processing means is adapted to determine at both of the phase error and the amplitude error.
